(19) United States
(12) Patent Application Publication
(10) Pub. No.: US 2012/0126204 A1
(43) Pub. Date: May 24, 2012

(54) IR PHOTODETECTORS WITH HIGH DETECTIVITY AT LOW DRIVE VOLTAGE

(75) Inventors: Franky So, Gainesville, FL (US); Do Young Kim, Gainesville, FL (US); Galileo Sarasqueta, Chandler, AZ (US); Bhabendra K. Pradhan, Marietta, GA (US)

(73) Assignees: NANOHOLDINGS, LLC, Rowayton, CT (US); UNIVERSITY OF FLORIDA RESEARCH FOUNDATION, INC., Gainesville, FL (US)

(21) Appl. No.: 13/272,995

(22) Filed: Oct. 13, 2011

Related U.S. Application Data
(60) Provisional application No. 61/416,630, filed on Nov. 23, 2010.

(51) Int. Cl. H01L 51/46; H01L 51/44

(52) U.S. Cl. 257/21; 257/40; 257/E51.026; 257/E51.015

(57) ABSTRACT

An IR photodetector with high detectivity comprises an IR sensitizing layer situated between an electron blocking layer (EBL) and a hole blocking layer (HBL). The EBL and HBL significantly reduce the dark current, resulting in a high detectivity while allowing use of a low applied voltage to the IR photodetector.

### CROSS-REFERENCE TO RELATED APPLICATION

The present application claims the benefit of U.S. Provisional Application Ser. No. 61/416,630, filed Nov. 23, 2010, which is hereby incorporated by reference herein in its entirety, including any figures, tables, or drawings.

### BACKGROUND OF INVENTION

Existing night vision goggles are complex electro-optical devices that intensify existing light instead of relying on their own light source. In a typical configuration, a conventional lens, called the objective lens, captures ambient light and some near-infrared light. The gathered light is then sent to an image-intensifier tube. The image-intensifier tube uses a photo cathode to collect photons of light energy for the generation of electrons. As the electrons pass through the tube, more electrons can be released from atoms in the tube, multiplying the original number of electrons by a factor of thousands, often accomplished using a micro channel plate (MCP). The image-intensifier tube can be positioned such that a cascade of electrons hits a screen coated with phosphors at the end of the tube with the electrons retaining the position of the channel through which they passed. The energy of the electrons causes the phosphors to reach an excited state and release photons, which create a green image on the screen and characterize state of the art night vision. The green phosphor image can be viewed through an ocular lens where the image is magnified and focused.

Recently, light up-conversion devices have attracted a great deal of research interest because of their potential applications in night vision, range finding, security, and semiconductor wafer inspections. Early near infrared (NIR) up-conversion devices were mostly based on the heterojunction structure of inorganic semiconductors, where a photodetecting and a luminescent section are in series. The up-conversion devices are mainly distinguished by the method of photodetection. Currently inorganic and hybrid up-conversion devices are expensive to fabricate and the processes used for fabricating these devices are not compatible with large area applications. Efforts are being made to achieve low cost up-conversion devices that have higher conversion efficiencies. Unfortunately, none have been identified to allow sufficient detectivity at low drive voltages, generally because of a high dark current density that leads to insufficient contrast in the photodetector. Hence, there remains a need to achieve high contrast in an up-conversion device and an IR photodetector with high detectivity while requiring low drive voltages, for example, about 10V.

### BRIEF SUMMARY

Embodiments of the invention are directed to infrared (IR) photodetectors comprising an IR sensitizing layer separating an electron blocking layer (EBL) and a hole blocking layer (HBL), wherein the IR photodetector has high detectivity. The IR photodetectors can be used at voltages below 20V. IR sensitizing layers of perylene-3,4,9,10-tetracarboxylic-3,4,9,10-dianhydride (PCTDA), tin (II) phthalocyanine (SnPc), SnPc:C₆₀, aluminum phthalocyanine chloride (AlPcCl), AlPcCl:C₆₀, titanyl phthalocyanine (TiOPc), TiOPc:C₆₀ PbSe quantum dots (QDs), PbS QDs, PbSe thin films, PbS thin films, InAs, InGaAs, Si, Ge, or GaAs can be used. The EBL can be poly(9,9-dioctyl-fluorene-co-N-(4-butylphenyl)diphenylamine) (TFB), Poly-N,N-bis-4-butylphenyl-N,N-bis-phenylbenzidine (poly-TPD), or polystyrene-N,N-diphenyl-N,N-bis(4-n-butylphenyl)-(1,10-biphenyl)-4,4-diamine-perfluorocyclobutane (PS-TPD-PFCB) and the HBL can be 2,9-Dimethyl-4,7-diphenyl-1,10-phenanthroline (BCP), p-bis(triphenylsilyl)benzene (UGH2), 4,7-diphenyl-1,10-phenanthroline (BPhen), tris-(8-hydroxy quinoline) aluminum (Alq₃), 3,5′-N,N′-dicarbazole-benzene (mCP), C₆₀, tris[3-(3-pyridyl)-mesityl]borane (3TPYMB), ZnO thin films, ZnO nanoparticles, TiO₂ thin films, or TiO₂ nanoparticles.

### BRIEF DESCRIPTION OF DRAWINGS

FIG. 1 shows a schematic for an infrared photodetector with high detectivity according to an embodiment of the invention.

FIG. 2 shows a) a schematic diagram and b) dark J-V characteristics of organic photodetector without and with a hole blocking layer and/or an electron blocking layer, and (c) detectivity of an organic photodetector with both hole and electron blocking layer as a function of wavelength, according to an embodiment of the invention.

FIG. 3 shows a) the chemical structures of EBL and HBL materials and a TEM image of the IR sensitizing material used to prepare IR photodetectors, according to an embodiment of the invention, b) typical absorption spectra of various sized PbSe QD nanocrystals with an insert of a TEM image of the quantum dots, and c) a schematic of an energetic structure for an IR photodetector with a reduced dark current.

FIG. 4 shows a) a plot of the current-voltage (J-V) characteristics of PbSe quantum dot comprising photodetectors without and with an HBL and an EBL, according to an embodiment of the invention, in a dark (J_{d}) and an illumination (Jₚₕ) state upon irradiation at λ=830 nm, b) the dark currents, photo-currents, and calculated detectivity values for various IR photodetectors under a −0.5V bias, and c) detectivity curves across the visible and IR spectrum for photo-detectors without and with an HBL and an EBL calculated from spectral response curves biased at −0.5V.

### DETAILED DISCLOSURE

Embodiments of the invention are directed to an infrared photodetector with high detectivity for use as a sensor and for use in an up-conversion device. When the dark current is the dominant noise factor, detectivity can be expressed as the following equation (1).

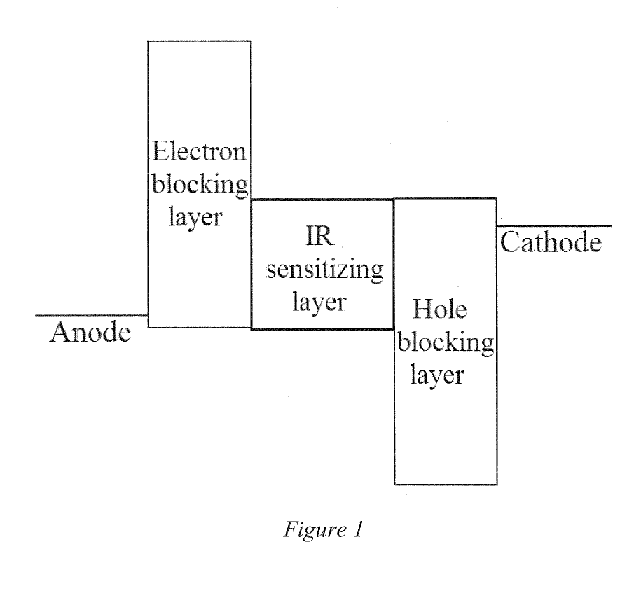

D*=R(2qJ_{d})^{1/2} (1)

where R is the responsivity, J_{d} is the dark current density, and q is the elementary charge (1.6×10⁻¹⁹ C). To achieve a photodetector with an optimal detectivity, a very low dark current density is required. The photodetectors, according to embodiments of the invention, comprise a hole blocking layer (HBL) with a deep highest occupied molecule orbital (HOMO) and an electron blocking layer (EBL) with a high lowest unoccupied molecule orbital (LUMO), where the EBL is situated on the anode facing surface and the HBL is situated on the cathode facing surface of an IR photosensitive layer, as shown in FIG. 1. The layers can range from about 20 nm to about 500 nm in thickness, and where the overall spacing between electrodes is less than 5 μm. The IR photodetector, according to embodiments of the invention, allows high detectivity at applied voltages less than 5V.

In embodiments of the invention, the IR photosensitive layer can be an organic or organometallic comprising material or an inorganic material. In some embodiments of the invention, the material absorbs through a large portion of the IR, extending beyond the near IR (700 to 1400 nm), for example, to wavelengths up to 1800 nm or greater. Exemplary organic or organometallic comprising materials include: perylene-3,4,9,10-tetracarboxylic-3,4,9,10-dianhydride (PCTDA); tin (II) phthalocyanine (SnPc); SnPc:C₆₀; aluminum phthalocyanine chloride (AlPcCl); AlPcCl:C₆₀; titanyl phthalocyanine (TiOPc); and TiOPc:C₆₀. Inorganic materials for use as photosensitive layers include: PbSe quantum dots (QDs); PbS QDs; PbSe thin films; PbS thin films; InAs; InGaAs; Si; Ge; and GaAs.

In embodiments of the invention, the HBL can be an organic or organometallic comprising material including, but not limited to: 2,9-Dimethyl-4,7-diphenyl-1,10-phenanthroline (BCP); p-bis(triphenylsilyl)benzene (UGH2); 4,7-diphenyl-1,10-phenanthroline (BPhen); tris-(8-hydroxy quinoline) aluminum (Alq₃); 3,5′-N,N′-dicarbazole-benzene (mCP); C₆₀; and tris[3-(3-pyridyl)-mesityl]borane (3TPYMB). In other embodiments of the invention, the HBL can be an inorganic material including, but not limited to, thin films or nanoparticles of ZnO or TiO₂.

In embodiments of the invention, the EBL can be an organic material, including, but not limited to: poly(9,9-dioctyl-fluorene-co-N-(4-butylphenyl)diphenylamine) (TFB); 1,1-bis[(di-4-tolylamino)phenyl]cyclohexane (TAPC); N,N′-diphenyl-N,N′(2-naphthyl)-(1,1′-phenyl)-4,4′-diamine (NPB); N,N′-diphenyl-N,N′-di(m-tolyl) benzidine (TPD); poly-N,N′-bis-4-butylphenyl-N,N′-bis-phenylbenzidine (poly-TPD); or polystyrene-N,N-diphenyl-N,N-bis(4-n-butylphenyl)-(1,10-biphenyl)-4,4-diamine-perfluorocyclobutane (PS-TPD-PFCB).

### METHODS AND MATERIALS

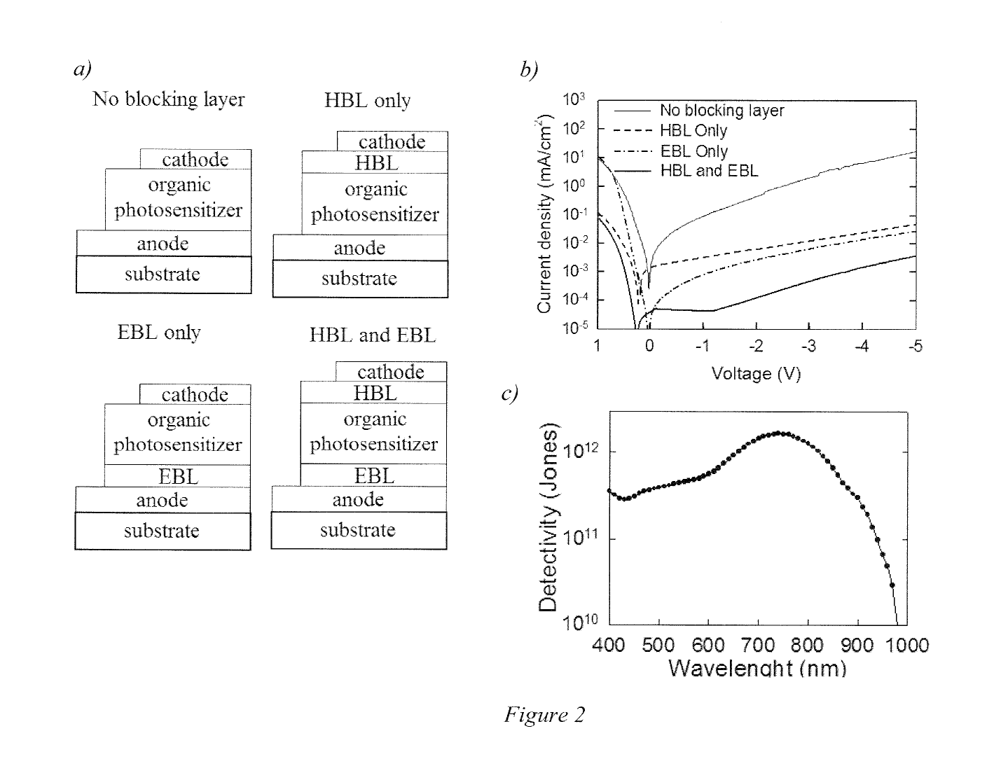

Photodetectors were prepared having no blocking layer, poly-TPD as an EBL, ZnO nanoparticles as a HBL, and with poly-TPD and ZnO nanoparticles as an EBL and a HBL, respectively, as shown in FIG. 2a, where the IR photosensitive layer comprised PbSe nanocrystals. As can be seen in FIG. 2b, the dark current-voltage (J-V) plots for the photodetectors decreased by more than 3 orders of magnitude from that with an EBL and a HBL from the photodetector that is blocking layer free. The photodetector with both blocking layers shows a detectivity of more than 10¹¹ Jones over IR and visible wavelengths smaller than 950 nm.

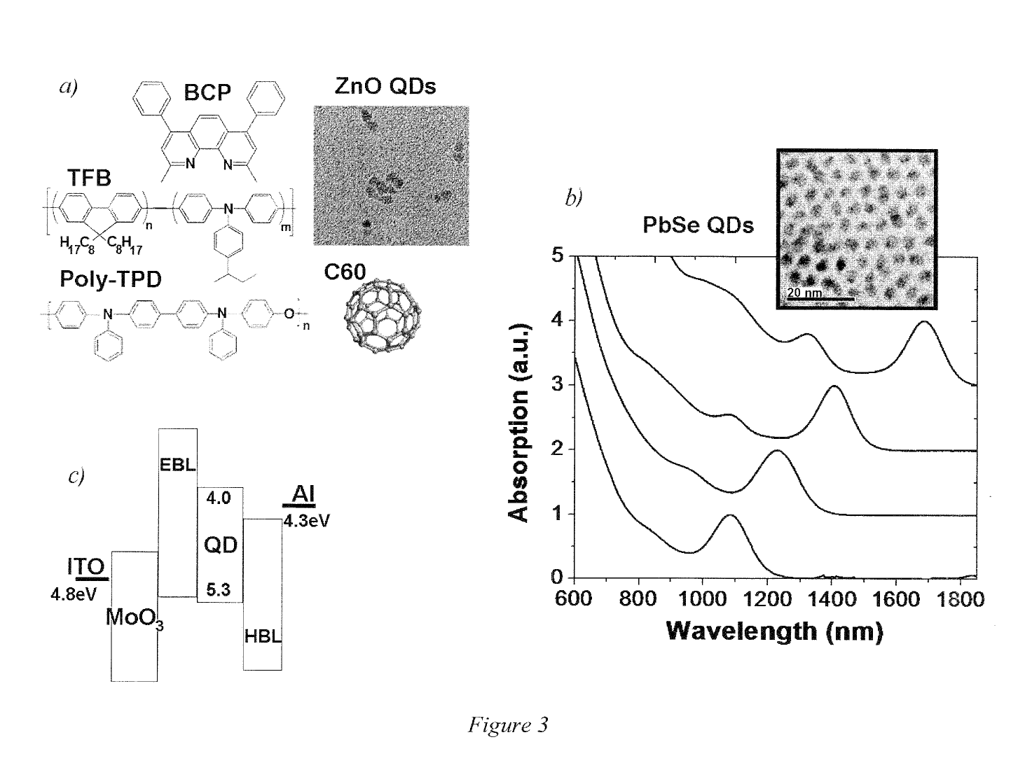

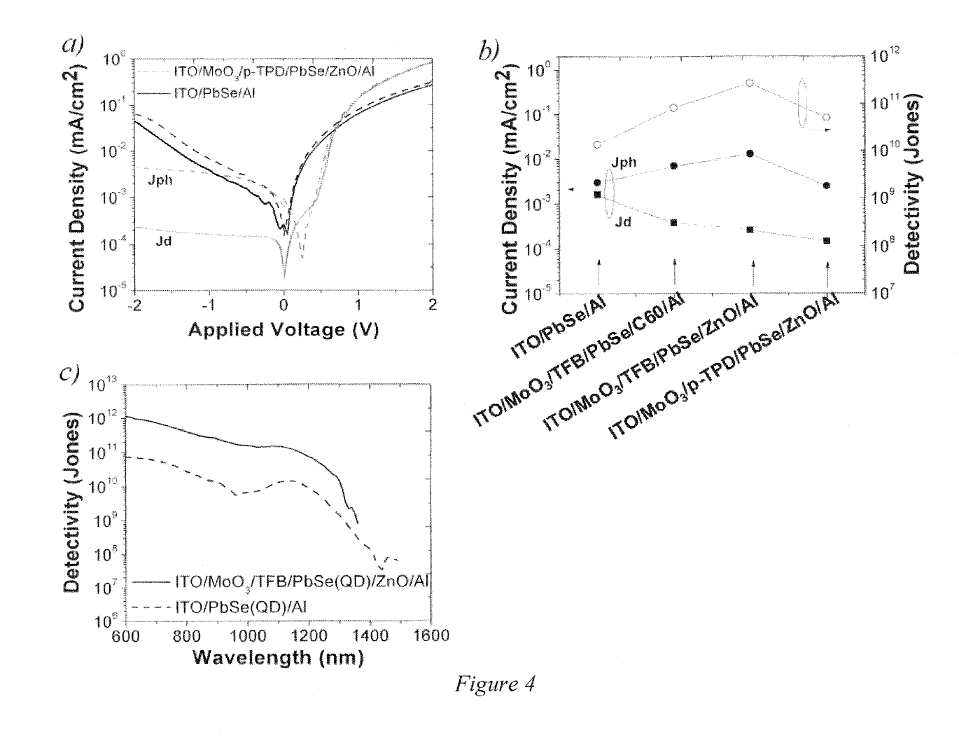

Inorganic nanoparticle photodetectors were also constructed having no blocking layers and with EBL and HBL layers. The photodetector, as schematically illustrated in FIG. 3c, comprised various HBLs (BCP, C60, or ZnO), EBLs (TFB or poly-TPD), whose structures are shown in FIG. 3a, and where PbSe quantum dots comprised the IR photosensitive layer, which is shown in FIG. 3b as a TEM image as an insert to the layers' IR absorption spectrum. The HOMO and LUMO levels of these blocking materials are given in Table 1, below. Although the magnitude of reduction differs, placement of an EBL and a HBL on the PbSe comprising photodetector results in a significant reduction of the dark current at low applied voltages, as shown in FIG. 4a. FIG. 4b is a plot of the dark current, photo current, and detectivity of the PbSe comprising photodetector without and with the various blocking layer systems. FIG. 4c shows the enhancement in the detectivity as a function of wavelength that results by having an EBL and a HBL.

TABLE 1
Blocking Layer Materials and their HOMO and LUMO Energies

| | HOMO Energy | LUMO Energy | |
|---|---|---|---|
| Material | in eV | in eV | Type of Layer |
| TFB | −5.3 | −2.1 | Electron Blocking |
| Poly-TPD | −5.1 | −2.3 | Electron Blocking |
| C₆₀ | −6.2 | −4.3 | Hole Blocking |
| BCP | −6.5 | −1.9 | Exciton/Hole Blocking |
| ZnO (NC) | −7.6 | −4.2 | Hole Blocking |

It should be understood that the examples and embodiments described herein are for illustrative purposes only and that various modifications or changes in light thereof will be suggested to persons skilled in the art and are to be included within the spirit and purview of this application.

We claim:

1. An IR photodetector, comprising an IR sensitizing layer separating an electron blocking layer (EBL) and a hole blocking layer (HBL), wherein the IR photodetector has high detectivity.

2. The IR photodetector of claim 1, wherein the IR sensitizing layer comprises perylene-3,4,9,10-tetracarboxylic-3,4,9,10-dianhydride (PCTDA), tin (II) phthalocyanine (SnPc), SnPc:C₆₀, aluminum phthalocyanine chloride (AlPcCl), AlPcCl:C₆₀, titanyl phthalocyanine (TiOPc), or TiOPc:C₆₀.

3. The IR photodetector of claim 1, wherein the IR sensitizing layer comprises PbSe quantum dots (QDs), PbS QDs, PbSe, PbS, InAs, InGaAs, Si, Ge, or GaAs.

4. The IR photodetector of claim 1, wherein the EBL comprises poly(9,9-dioctyl-fluorene-co-N-(4-butylphenyl)diphenylamine) (TFB), Poly-N,N-bis-4-butylphenyl-N,N-bis-phenylbenzidine (poly-TPD), or polystyrene-N,N-diphenyl-N,N-bis(4-n-butylphenyl)-(1,10-biphenyl)-4,4-diamine-perfluorocyclobutane (PS-TPD-PFCB).

5. The IR photodetector of claim 1, wherein the HBL comprises 2,9-Dimethyl-4,7-diphenyl-1,10-phenanthroline (BCP), p-bis(triphenylsilyl)benzene (UGH2), 4,7-diphenyl- 1,10-phenanthroline (BPhen), tris-(8-hydroxy quinoline) aluminum (Alq₃), 3,5′-N,N′-dicarbazole-benzene (mCP), C₆₀, or tris[3-(3-pyridyl)-mesityl]borane (3TPYMB).

6. The IR photodetector of claim 1, wherein the HBL comprises continuous or nanoparticulate films of ZnO or TiO₂.
